(19) United States
(12) Patent Application Publication
(10) Pub. No.: US 2026/0251693 A1
(43) Pub. Date: Aug. 27, 2026

(54) CAPACITOR LEAK DETECT AND RETIRE

(71) Applicant: Micron Technology, Inc., Boise, ID (US)

(72) Inventors: Mingdong Cui, Folsom, CA (US); Makoto Kitagawa, Folsom, CA (US); Daniele Vimercati, El Dorado Hills, CA (US); Duane R. Mills, Shingle Springs, CA (US); Eric S. Carman, San Francisco, CA (US)

(21) Appl. No.: 19/543,320

(22) Filed: Feb. 18, 2026

Related U.S. Application Data
(60) Provisional application No. 63/762,975, filed on Feb. 25, 2025.

(51) Int. Cl. G01R 31/27; G01R 31/26; G11C 11/4091; G11C 29/02; G11C 29/50

(52) U.S. Cl. CPC G01R 31/275; G01R 31/2637; G11C 29/026; G11C 29/50; G11C 11/4091; G11C 2029/5006

(57) ABSTRACT

A variety of applications can include an electronic device having a circuit on a die, where the circuit has an input to receive a signal, with a decoupling capacitor on the die coupled to the input. A detection circuit on the die can be coupled to the decoupling circuit, where the detection circuit can be structured to detect leakage current from the decoupling capacitor and to disable the decoupling capacitor in response to detection of the leakage current. The circuit can be implemented as a circuit in a memory die to perform functions for memory cells of a memory array of the memory device.

### PRIORITY APPLICATION

This application claims the benefit of priority to U.S. Provisional Application Ser. No. 63/762,975, filed Feb. 25, 2025, which is incorporated herein by reference in its entirety.

### FIELD OF THE DISCLOSURE

Embodiments of the disclosure relate generally to electronic devices and systems, and more specifically, to memory devices, components of memory devices, operation of the memory devices, and formation thereof.

### BACKGROUND

Memory devices are typically provided as internal, semiconductor, integrated circuits (ICs) in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices can be improved by enhancements to the design, operation, and fabrication of components of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 is a representation of example components of an electronic device on a die, in accordance with various embodiments.

FIG. 2 is a representation of example components of a die of a memory device having a set of detection circuits for a circuit decoupling capacitor to a circuit on the die, in accordance with various embodiments.

FIG. 3 illustrates a relationship between an example detection enable signal to detection circuits of FIG. 2 and a switch control signal to a switch in the detection circuits, in accordance with various embodiments.

FIG. 4 illustrates an example of a pulse train for a detection enable signal that can be implemented to conduct automatic detect and retire of a decoupling capacitor of a decoupling capacitor network in the die of the memory device of FIG. 2, in accordance with various embodiments.

FIG. 5 is a representation of example components of a die of a memory device having a set of detection circuits for a circuit decoupling capacitor to a circuit on the die, in accordance with various embodiments.

FIG. 6 is a representation of example components of a memory die having a set of detection circuits for a circuit decoupling capacitor to a circuit on the die, in accordance with various embodiments.

FIG. 7 shows an example of timing of signals that provides a current at a test pad for testing in the memory device of FIG. 6, in accordance with various embodiments.

FIG. 8 illustrates the status of select signals in the memory device of FIG. 6, after a fuse in a detection circuit is blown, in accordance with various embodiments.

FIG. 9 represents an example memory cell of a dynamic random-access memory, in accordance with various embodiments.

FIG. 10 represents an example of a modified memory cell that can be implemented in the dynamic random-access memory that includes an array of the memory cells of FIG. 9, in accordance with various embodiments.

FIG. 11 is a representation of example components of a die of a memory device having a detection circuit for a decoupling capacitor using the modified memory cell of FIG. 10 in the architecture of FIG. 5, in accordance with various embodiments.

FIG. 12 illustrates an example capacitor applicable as a decoupling capacitor controlled by a switch of a detection circuit in a three-dimensional dynamic random-access memory, in accordance with various embodiments.

FIG. 13 is a circuit representation of the transistors and connections shown in FIG. 12, in accordance with various embodiments.

FIG. 14 is a flow diagram of features of an example method of controlling a decoupling capacitor in a die of a memory device, in accordance with various embodiments.

FIG. 15 is a block diagram illustrating an example of a machine that can include one or more integrated circuits having capacitor leak detect and retire components, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

Memory dies include an array of memory cells and circuits to manage the memory cells. Some of the circuits include inputs that are coupled to decoupling capacitors. A decoupling capacitor is a capacitor to decouple at least a portion of a signal to an input of a circuit to prevent electrical energy, associated with the signal, from transferring to the input. A decoupling capacitor can be used to shunt noise accompanying the signal away from the input to the circuit. The decoupling capacitor can be implemented at a node between a power supply to the circuit and the input to the circuit. If such a decoupling capacitor is defective with a short, the circuit can become inoperable or function incorrectly. Such defects can cause yield loss in manufacturing. Additionally, inline defects can occur when the voltage stress causes the capacitor to break and becomes shorted between its two terminals during operation of the memory die after manufacturing, reducing the lifetime of the memory die in a user application.

In a 3D DRAM, a significant number of memory cells can be fabricated that are not used for storing data and that can be applied to other functions. The structure of a DRAM memory cell includes a transistor coupled to a capacitor. The transistor is a selector of the capacitor to which it is coupled and can be referred to as a selector, selector transistor, or an access transistor. Cell capacitors of formed memory cells, not to be used for data, can be grouped together to be used as a capacitor such as a decoupling capacitor of a power bus on a die of a 3D DRAM. Such a decoupling capacitor can be a capacitor of a capacitor network. A capacitor structured from a group of memory cells can be referred to as a storage container capacitor. Depending on the defect rate of forming such capacitors, formation of 3D DRAMs may suffer initial yield loss or failure during usage when an individual capacitor is broken by shorting.

In various embodiments, a method can be implemented to detect and disconnect a shorted capacitor to protect a die to keep the die functional. A detection circuit can be integrated in the die with the detection circuit coupled to a capacitor to maintain the capacitor operational when a defect is not detected and to remove the capacitor when the capacitor is determined to be defective. The status of the capacitor can be monitored by determining the presence of leakage current in operation of the capacitor. With a capacitor being structured as a capacitor network, removal of one or more capacitors from the capacitor network can result in acceptable operation of the circuit to which the capacitor network is coupled. The removal of the one or more capacitors can be accomplished by effectively disconnecting the one or more capacitors, which retires these capacitors from operation of the die. The detection circuit can be structured to have a small current detector to detect leakage current and shut off the capacitor if there is leakage detected. Detection of leakage can be specified to be detection of leakage current greater than a threshold amount of current leakage. The operation of the detection circuit can be started using a pulse, which can be applied either during power-up or during active operations, without interference to normal die operation. This method can be implemented in a 3D DRAM, for example, using an existing selector of a storage container capacitor as an on/off switch.

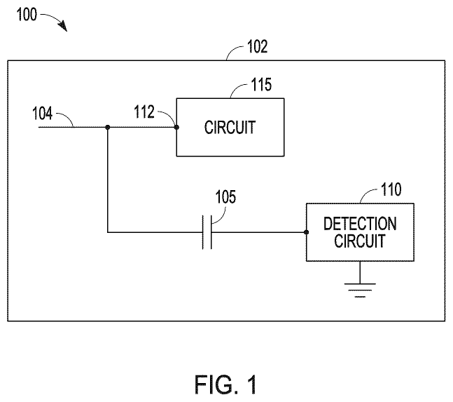

FIG. 1 is a representation of an embodiment of example components of an electronic device 100 on a die 102. Electronic device 100 includes a circuit 115 on die 102, where circuit 115 has an input 112 to receive a signal. The signal can be provided to input 112 by a conductive line 104. A decoupling capacitor 105 is located on die 102 and is coupled to input 112 via conductive line 104. Decoupling capacitor 105 can be coupled to a detection circuit 110 located on die 102. Detection circuit 110 can be structured to detect leakage current from decoupling capacitor 105 and to disable decoupling capacitor 105 in response to detection of the leakage current. When the status of decoupling capacitor 105 is determined to be non-leaking, decoupling capacitor 105 can be coupled to a reference voltage via detection circuit 110. The reference voltage can be at a node that is part of detection circuit 110. The reference voltage can be a voltage source supply (VSS), which can be a stable voltage. A non-leaking status occurs when leakage of current from decoupling capacitor 105 is less than a threshold current. The threshold current can depend on the architecture of electronic device 100 or the application of electronic device 100. Though the threshold current can be zero for a specified electronic device in a particular application, the threshold current can be a small current limited by the specifications for input 112. Electronic device 100 can be a memory device such as but not limited to a 3D DRAM.

Decoupling capacitor 105 can be one decoupling capacitor of a decoupling capacitor network coupled to input 112 of circuit 115. The decoupling capacitor network can be a circuit decoupling capacitor to input 112. The decoupling capacitor network can include a sufficient number of capacitors to maintain operation of circuit 115 within operational specifications and maintain decoupling for circuit 115 to allow retirement of multiple decoupling capacitors of the decoupling capacitor network. The sufficient number of capacitors can be a number to allow retirement of ten percent of the capacitors of the decoupling capacitor network, while maintaining operation of the circuit within operational specifications. The sufficient number of capacitors can be a number to allow retirement of one percent of the capacitors of the decoupling capacitor network, while maintaining operation of the circuit within operational specifications. Other retirement percentages can be implemented depending on the application or specifications for electronic device 100.

Detection circuit 110 can include a comparison circuit with a sinking current. Alternatively, detection circuit 110 can include a comparison circuit with a sourcing current. Detection circuit can include a switch to enable decoupling operation of the decoupling capacitor by operatively coupling the decoupling capacitor to a reference voltage. The switch can be controlled by a switch control signal to enable the decoupling operation or to disable the decoupling operation. The switch can be a metal-oxide-semiconductor (MOS) field effect transistor (FET). The gate of MOSFETs can be a conductive material other than a metal. The switch can be a transistor that is larger than other transistors in detection circuit 110.

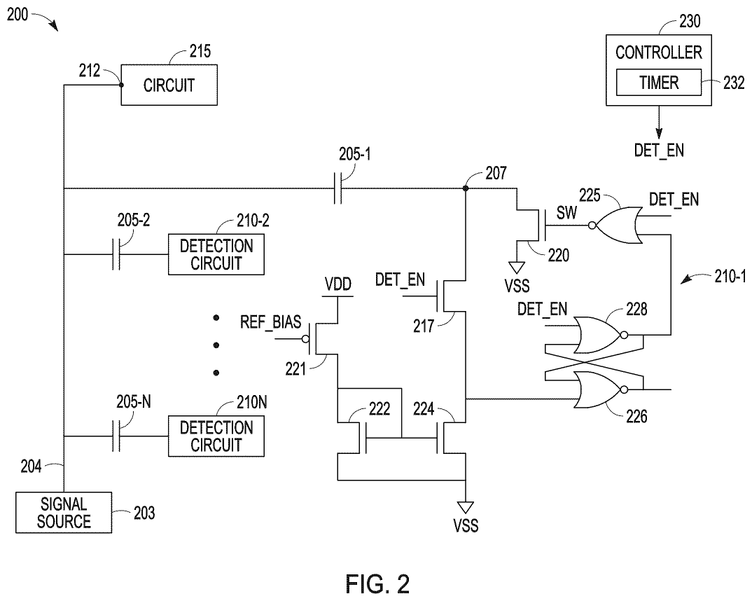

FIG. 2 is a representation of an embodiment of example components of a die of a memory device 200 having a set of detection circuits for a circuit decoupling capacitor to a circuit 215 on the die. The circuit decoupling capacitor can decouple noise from a signal to an input 212 of circuit 215 via a conductive line 204 from a signal source 203. Signal source 203 on the die of memory device 200 can be, but is not limited to, a power source for circuits on the die or a node providing power from external to the die. Conductive line 204 can be, but is not limited to, a power bus or other line that can provide a supply voltage to a circuit on the die. A supply voltage, V_{CCP}, can be supplied to input 212 via conductive line 204. V_{CCP} is an elevated voltage above a supply voltage V_{CC} used in circuits of memory device 200. Circuit 215 can be, but is not limited to, a sense amplifier or other circuit used to manage the functionalities of memory device 200.

The circuit decoupling capacitor to input 212 of circuit 215 can be composed of multiple decoupling capacitors 205-1, 205-2 . . . 205-N. Decoupling capacitor 205-1 can be coupled to a detection circuit 210-1 such that decoupling capacitor 205-1 is coupled to a node having a voltage reference V_{SS} to decouple a noise signal to input 212. Detection circuit 210-1 can include a switch 220 through which decoupling capacitor 205-1 couples to V_{SS} to decouple a noise signal from input 212. Switch 220 can be, but is not limited to, a n-type metal oxide semiconductor field effect transistor (N-MOSFET also known as a NMOS transistor). Switch 220 can be turned off to detect the status of decoupling capacitor 205-1 as to whether decoupling capacitor 205-1 is effectively shorted and produces a leakage current. The detection of a level of leakage current identifies the status of decoupling capacitor 205-1 to be a defective decoupling capacitor. The detection of a lack of the level of leakage current identifies the status of decoupling capacitor 205-1 to be a non-defective decoupling capacitor. When determined to be defective, decoupling capacitor 205-1 can be retired from operation by disconnecting the decoupling capacitor 205-1 from being connected to a stable supply. Detection circuit 210-1 can automatically detect and retire decoupling capacitor 205-1 following decoupling capacitor 205-1 becoming a defective component due to its level of leakage current.

A detection enable signal, DET_EN, from a controller 230 on the die containing detection circuit 210, can be used to turn switch 220 off and turn on a pass transistor 217 to couple a current mirror that is coupled to decoupling capacitor 205-1 through node 207. The current mirror can be provided by a supply voltage of VDD coupled to a p-type MOS (PMOS) transistor 221 having a gate arranged to receive a reference bias, REF_BIAS, where VDD provides, through PMOS transistor 221, a reference current to a NMOS transistors 222 and 224. The sources of NMOS transistors 222 and 224 can be coupled to VSS, which can be a local VSS. REF_BIAS can be provided by controller 230 or another source. REF_BIAS can be provided as a signal to turn on and off PMOS transistor 221 coordinated with DET_EN or as a constant voltage providing the reference current while the memory device is on. A feedback circuit couples the current mirror to switch 220. The source of pass transistor 217 is coupled to the drain of NMOS transistor 224 at a node coupled to an input of a SR latch defined by NOR gates 226 and 228. Another input to the SR latch is arranged to receive DET_EN. An output signal of the SR latch can be input to a NOR gate 225, with NOR gate 225 having another input to receive DET_EN. A switch control signal, SW, can be provided to the gate of switch 220 to turn off or on switch 220, where, with switch 220 on, node 207 is operatively coupled to VSS and, with switch 220 off, node 207 is not operatively coupled to VSS through switch 220.

At power-up of memory device 200, the inputs to NOR gate 225 are low and SW is set to a high, turning on switch 220. Following power-up, controller 230 can generate DET_EN as a positive pulse to detection circuit 210, which places a high signal for DET_EN to NOR gate 225 and to NOR gate 228 of the SR latch, along with turning on pass transistor 217. If decoupling capacitor 205-1 is not defective with the positive pulse being high, the input provided to NOR gate 226 of the SR latch remains low and the output of the SR latch to NOR gate 225 is low and switch 220 turns off. When the positive pulse goes low, with the decoupling capacitor 205-1 not being defective, the inputs to the SR latch are low and the output of the SR latch remains at the previous low. With DET_EN low and the output of the SR latch low, NOR gate 225 places SW high to switch 220, turning switch 220 on and coupling decoupling capacitor 205-1 to VSS, with the path from node 207 to the SR latch cut-off by PMOS transistor 221.

Following power-up, if decoupling capacitor 205-1 is defective with the positive pulse being high, the input provided to the SR latch rises. With both inputs to the SR latch being high, the output of the SR latch provided to NOR gate 225 remains at a low and switch 220 turns off. If decoupling capacitor 205-1 is defective with the positive pulse going low and the voltage at the input of NOR gate 226 having risen to a high due to the leakage, the output of the SR latch, which is provided to NOR gate 225, is a high input, placing SW to a low, which keeps switch 220 off. With switch 220 off with DET_EN low and pass transistor 217 off, node 207 at one end of decoupling capacitor 205-1 is not connected to VSS or other potential and is in a floating condition. With node 207 floating, the remaining components of the die of memory device 200 are not affected. Floating node 207 disconnects decoupling capacitor 205-1 from a shorting defect operation with respect to circuit 215, retiring decoupling capacitor 205-1 in memory device 200. The automatic detection and retirement scheme of decoupling capacitor 205-1 provided by detection circuit 210-1 can avoid the failure of memory device 200 that can be caused by a defective decoupling capacitor 205-1 shorting input 212 to ground without the use of detection circuit 210-1. If decoupling capacitor 205-1 is the only decoupling capacitor to input 212 of circuit 215, then noise would not be decoupled from input 212 when decoupling capacitor 205-1 is retired, leading to degraded operation of circuit 215.

The structure of each combination of decoupling capacitors 205-2 . . . 205-N with detection circuits 210-1 . . . 210-N, respectively, as shown in FIG. 2, can be similar or identical to the structure of the combination of decoupling capacitor 205-1 with detection circuit 210-1, such that these combinations operate in the same manner as the combination of decoupling capacitor 205-1 with detection circuit 210-1. With occurrences of defects of decoupling capacitors 205-1 . . . 205-N being independent of each other in a decoupling capacitor network, acceptable operation of memory device 200 within specifications can be maintained with the retirement of a one or more decoupling capacitors 205-1 . . . 205-N, given a sufficient number N of decoupling capacitors. The decoupling capacitor network can include a sufficient number of decoupling capacitors to maintain operation of the circuit within operational specifications and maintain decoupling for the circuit to allow retirement of multiple decoupling capacitors of the decoupling capacitor network. The sufficient number of decoupling capacitors can be a number to allow retirement of ten percent of the decoupling capacitors of the decoupling capacitor network, while maintaining operation of the circuit within operational specifications. In a variation, the sufficient number of decoupling capacitors can be a number to allow retirement of one percent of the decoupling capacitors of the decoupling capacitor network. The sufficient number is a threshold that can be determined by process and design parameters. Though implementation of sets of detection circuits uses additional area of the die, the associated costs of using additional area can be offset by increased yield of producing the memory dies and reduction in failure of the memory dies in the lifetime of operation of the memory die in an apparatus. Alternatively, based on yield parameters, the automatic detection and retirement provided by the combinations of decoupling capacitors 205-1 . . . 205-N and detection circuits 210-1 . . . 210-N, as shown in FIG. 2, allows for process flows that are not as stringent as process flows to obtain yields corresponding to memory dies without detection circuits 210-1 . . . 210-N.

Controller 230 can include a timer 232 or timing circuit to generate DET_EN as an enable pulse. Timer 232 can set the length of time that the enable pulse is high (width of the enable pulse) and the time after power-up at which the enable pulse is generated. The enable pulse can be generated as a single pulse during testing in fabrication to retire any of the decoupling capacitors 205-1 . . . 205-N in the decoupling capacitor network, while certifying that memory device 200 to be non-defective, if the number of defective decoupling capacitors in the decoupling capacitor network is within an acceptable specification. Alternatively, controller 230 can be structured for defect detection and retirement not only at testing in fabrication but also when memory device 200 is inline in an apparatus. Timer 232 or timing circuit can generate DET_EN as an enable pulse at start-up and subsequently periodically while operating inline in an apparatus. A first enable pulse of the periodically generated enable pulses can be generated at a time after generating the enable pulse at start-up that is longer than the time between the periodically generated enable pulses. Alternatively, automatic detection and retire can occur at random times with memory device 200 in an apparatus. Controller 230 can be structured to control detection circuits 210-1 . . . 210-N without affecting data storage operation of the die of memory device 200. Controller 230 can operate the automatic detection and retirement scheme as a background process.

The die of memory device 200 can be, but is not limited to, a DRAM die with each of decoupling capacitors 205-1 . . . 205-N structured from coupling a group of formed memory cells, where the memory cells are modified not to store data. The electrodes of the capacitors of these formed memory cells can be connected together to form a capacitor. Though the decoupling capacitor to input 212 and automatic detection and retirement can be implemented in memory device 200, such a construction can be implemented in IC devices other than on a memory die.

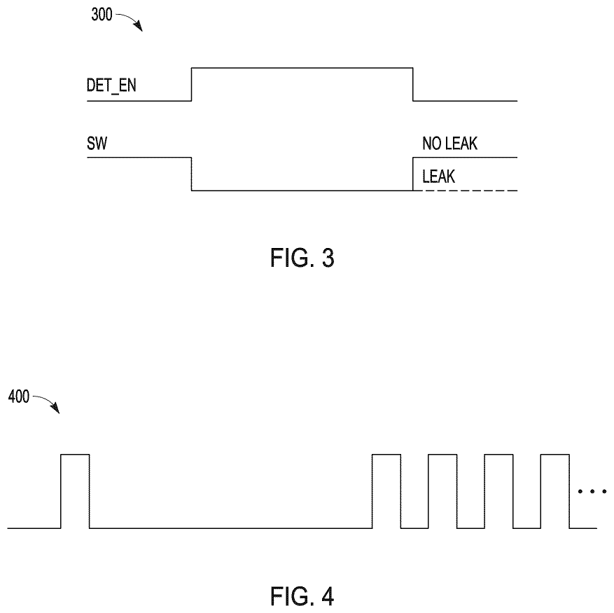

FIG. 3 illustrates a relationship 300 between an example embodiment of DET_EN to detection circuits of FIG. 2 and SW to the switches in the detection circuits. When DET_EN is high, SW can be low to turn off or keep switch 220 off. When DET_EN is low before going high, SW can be high placing switch 220 on. When DET_EN is low after going high, SW can be high identifying no leak of coupling capacitor 205-1 or SW can be low identifying a leak of coupling capacitor 205-1, where a leak can be defined with respect to a threshold current.

FIG. 4 illustrates an example of an embodiment of a pulse train 400 for DET_EN that can be implemented to conduct automatic detection and retirement of a decoupling capacitor of a decoupling capacitor network in the die of memory device 200 of FIG. 2. The pulse train can be used for memory device 200 operating in-line in an apparatus. Pulses of pulse train 400 can be generated at start-up and subsequently periodically. In various applications, a first pulse of the periodically generated pulses can be generated at a time after generating the pulse at start-up that is longer than time between the periodically generated pulses. A controller such as controller 230 of memory device 200 of FIG. 2 can set the time between pulses. The set time can be one sec, one minute, one hour, one week, or other appropriate time depending on the type of memory device, voltage level being applied, or application in which the memory device or other IC device can be implemented. Alternatively, in various applications, only the first pulse of pulse train 400 is generated for testing in the fabrication process.

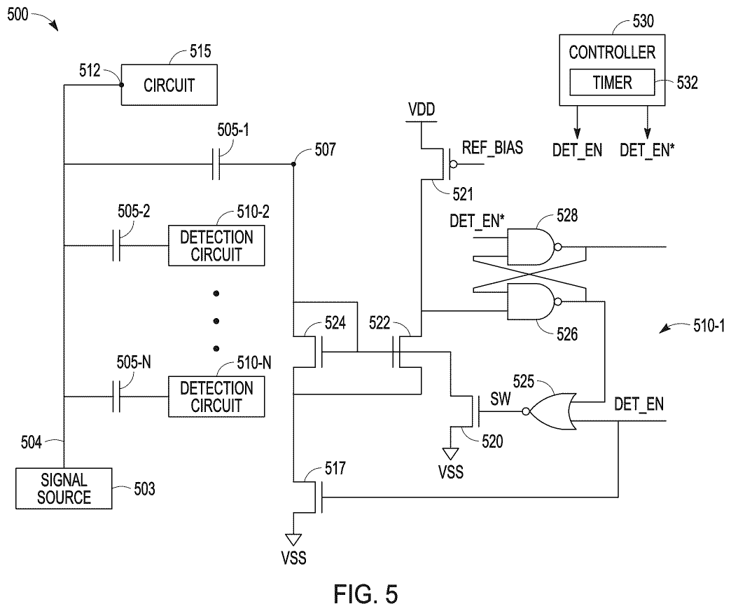

FIG. 5 is a representation of an embodiment of example components of a die of a memory device 500 having a set of detection circuits for a circuit decoupling capacitor to a circuit 515 on the die. The circuit decoupling capacitor can decouple noise from a signal to an input 512 of circuit 515 via a conductive line 504 from a signal source 503. Signal source 503 on the die of memory device 500 can be, but is not limited to, a power source for circuits on the die or a node providing power from external to the die. Conductive line 504 can be, but is not limited to, a power bus or other line that can provide a supply voltage to a circuit on the die. A supply voltage, V_{CCP}, can be supplied to input 512 via conductive line 504. Circuit 515 can be, but is not limited to, a sense amplifier or other circuit used to manage the functionalities of memory device 500.

The circuit decoupling capacitor to input 512 of circuit 515 can be composed of multiple decoupling capacitors 505-1, 505-2 . . . 505-N. Decoupling capacitor 505-1 can be coupled to a detection circuit 510-1 such that decoupling capacitor 505-1 is coupled to a node having a voltage reference V_{SS} to decouple a noise signal to input 512. Detection circuit 510-1 can include a switch 520 through which decoupling capacitor 505-1 couples to V_{SS} to decouple a noise signal from input 512. Switch 520 can be, but is not limited to, a NMOS transistor. Switch 520 can be turned off to detect the status of decoupling capacitor 505-1 as to whether decoupling capacitor 505-1 is shorted and produces a leakage current. The detection of a level of leakage current identifies status of decoupling capacitor 505-1 to be a defective decoupling capacitor. The detection of a lack of the level of leakage current identifies status of decoupling capacitor 505-1 to be a non-defective decoupling capacitor. When determined to be defective, decoupling capacitor 505-1 can be retired from operation by disconnecting the decoupling capacitor 505-1 from being connected to a closed circuit. Detection circuit 510-1 can automatically detect and retire decoupling capacitor 505-1 following decoupling capacitor becoming a defective component due to its level of leakage current.

A detection enable signal (DET_EN), from a controller 530 on the die containing detection circuit 510, can be used to turn switch 520 off and turn on a pass transistor 517 to couple a current mirror to VSS, which can be a local VSS. The current mirror can be provided by a supply voltage of VDD coupled to a PMOS transistor 521 having a gate arranged to receive a reference bias (REF_BIAS), where VDD provides, through PMOS transistor 521, a reference current to the drain of NMOS transistor 522. REF_BIAS can be provided by controller 530 or another source. REF_BIAS can be provided as a signal to turn on and off PMOS transistor 521 coordinated with DET_EN or as a constant voltage providing the reference current while memory device is on. A feedback circuit couples the current mirror to switch 520. The current mirror includes NMOS transistor 524, where the gates of NMOS transistors 522 and 524 are coupled to together and to node 507 and the sources of NMOS transistors 522 and 524 are coupled to pass transistor 517. The drain of NMOS transistor 522 is coupled to the source of PMOS transistor 521 and to a node coupled to an input of a SR latch defined by NAND gates 526 and 528. Another input to the SR latch is arranged to receive a complement of DET_EN (DET_EN*). The DET_EN* is low (0) when DET_EN is high (1) and is high when DET_EN is low. Controller 530 can generate DET_EN* or, alternatively, DET_EN* can be generated as output of an inverter having DET_EN as an input. An output signal of the SR latch can be input to a NOR gate 525, with NOR gate 525 having another input to receive DET_EN. A switch control signal, SW, can be provided to the gate of switch 520 to turn off or on switch 520, where, with switch 520 on, node 507 is operatively coupled to VSS and, with switch 520 off, node 507 is not operatively coupled to VSS through switch 520.

At power-up of memory device 500, the inputs to NOR gate 525 are low and SW is set to a high, turning on switch 520. Following power-up, controller 530 can generate DET_EN as a positive pulse to detection circuit 510, which places a high signal for DET_EN to NOR gate 525 and a low signal for DET_EN* to NAND gate 528 of the SR latch, along with turning on pass transistor 517. If decoupling capacitor 505-1 is not defective with DET_EN being high, the input provided to NAND gate 526 of the SR latch remains low and the output of the SR latch to NOR gate 525 is low and switch 520 remains off. When DET_EN goes low, with the decoupling capacitor 505-1 not being defective, DET_EN* to the SR latch is high and input to NAND gate 526 is low and the output of the SR latch remains at low. With DET_EN low and the output of the SR latch low, NOR gate 525 places SW high to switch 520, turning switch 520 on and coupling decoupling capacitor 505-1 to VSS that is coupled to switch 520.

Following power-up, if decoupling capacitor 505-1 is defective with DET_EN being high (DET_EN* low), the leakage current opposes the reference current and the input to NAND gate 526 is low. With both inputs to the SR latch being low, the output of the SR latch provided to NOR gate 525 remains at a low and switch 520 turns off. If decoupling capacitor 505-1 is defective with DET_EN going low (DET_EN* high) and the voltage at NAND gate 526 low, the output of the SR latch, which is provided to NOR gate 525, is high, placing SW to a low, which keeps switch 520 off. With switch 520 off with DET_EN low and pass transistor 517 off, node 507 at one end of decoupling capacitor 505-1 is not connected to VSS or other potential and is in a floating condition. With node 507 floating, the remaining components of the die of memory device 200 are not affected. Floating node 507 disconnects decoupling capacitor 505-1 from a shorting defect operation with respect to circuit 515, retiring decoupling capacitor 505-1 in memory device 500. The automatic detection and retirement scheme of decoupling capacitor 505-1 provided by detection circuit 510-1 can avoid the failure of memory device 500 that can be caused by a defective decoupling capacitor 505-1 shorting input 512 to ground without the use of detection circuit 510-1. If decoupling capacitor 505-1 is the only decoupling capacitor to input 512 of circuit 515, then noise would not be decoupled from input 512 when decoupling capacitor 505-1 is retired, leading to degraded operation of circuit 515.

The structure of each combination of decoupling capacitors 505-2 . . . 505-N with detection circuits 510-1 . . . 510-N, respectively, as shown in FIG. 5, can be similar or identical to the structure of the combination decoupling capacitor 505-1 with detection circuit 510-1, such that these combinations operate in the same manner as the combination of decoupling capacitor 505-1 with detection circuit 510-1. With occurrences of defects of decoupling capacitors 505-1 . . . 505-N being independent of each other in a decoupling capacitor network, acceptable operation of memory device 500 within specifications can be maintained with the retirement of a one or more decoupling capacitors 505-1 . . . 505-N. The decoupling capacitor network can include a sufficient number of decoupling capacitors to maintain operation of the circuit within operational specifications and maintain decoupling for the circuit to allow retirement of multiple decoupling capacitors of the decoupling capacitor network. The sufficient number of decoupling capacitors can be a number to allow retirement of ten percent of the decoupling capacitors of the decoupling capacitor network, while maintaining operation of the circuit within operational specifications. In a variation, the sufficient number of decoupling capacitors can be a number to allow retirement of one percent of the decoupling capacitors of the decoupling capacitor network. The sufficient number is a threshold that can be determined by process and design parameters. Though implementation of sets of detection circuits uses additional area of the die, the associated costs of using additional area can be offset by increased yield of producing the memory dies and reduction in failure of the memory dies in the lifetime of operation of the memory die in an apparatus. Alternatively, based on yield parameters, the automatic detection and retirement provided by the combinations of decoupling capacitors 505-1 . . . 505-N and detection circuits 510-1 . . . 510-N, as shown in FIG. 5, allows for process flows that are not as stringent as process flows to obtain yields corresponding to memory dies without detection circuits 510-1 . . . 510-N.

Controller 530 can include a timer 532 or timing circuit to generate DET_EN as an enable pulse. Timer 532 can set the length of time that DET_EN is high (width of the enable pulse) and the time after power-up at which DET_EN is generated. DET_EN can be generated as a single pulse during testing in fabrication to retire any of the decoupling capacitors 505-1 . . . 505-N in the decoupling capacitor network, while certifying that memory device 500 to be non-defective, if the number of defective decoupling capacitors in the decoupling capacitor network is within an acceptable specification. Alternatively, controller 530 can be structured for defect detection and retirement not only at testing in fabrication but also when memory device 200 is inline in an apparatus. Timer 532 or timing circuit can generate DET_EN as an enable pulse at start-up and subsequently periodically while operating inline in an apparatus. A first enable pulse of the periodically generated enable pulses can be generated at a time after generating the enable pulse at start-up that is longer than time between the periodically generated enable pulses. Alternatively, automatic detection and retire can occur at random times with memory device 500 in an apparatus. Controller 530 can be structured to control detection circuits 510-1 . . . 510-N without affecting data storage operation of the die of memory device 500. Controller 530 can operate the automatic detection and retirement scheme as a background process.

The die of memory device 500 can be, but is not limited to, a DRAM die with each of decoupling capacitors 505-1 . . . 505-N structured from coupling a group of formed memory cells, where the memory cells are modified not to store data. The electrodes of the capacitors of these formed memory cells can be connected together to form a capacitor. Though the decoupling capacitor to input 512 and automatic detection and retirement can be implemented in memory device 500, such a construction can be implemented in IC devices other than on a memory die.

The detection and retirement scheme of memory device 500 of FIG. 5 uses a sourcing current implementation of a current mirror while the detection and retirement scheme of memory device 200 of FIG. 2 uses a sinking current implementation of a current mirror. The detection and retirement scheme of memory device 200 can provide a better detect and retire procedure than the detection and retirement scheme of memory device 500 by improving noise tolerance during detection. The detection and retirement scheme of memory device 200 can avoid direct coupling between supply voltage ripple to detection signal. A leak trip point error (with supply noise) can be reduced by detection and retirement scheme of memory device 200 compared to detection and retirement scheme of memory device 500, for example, from approximately six μA down to approximately one μA. In addition, the detection and retirement scheme of memory device 200 decouples the mirror reference from switch 520, as compared to the detection and retirement scheme of memory device 500, providing switch noise reduction.

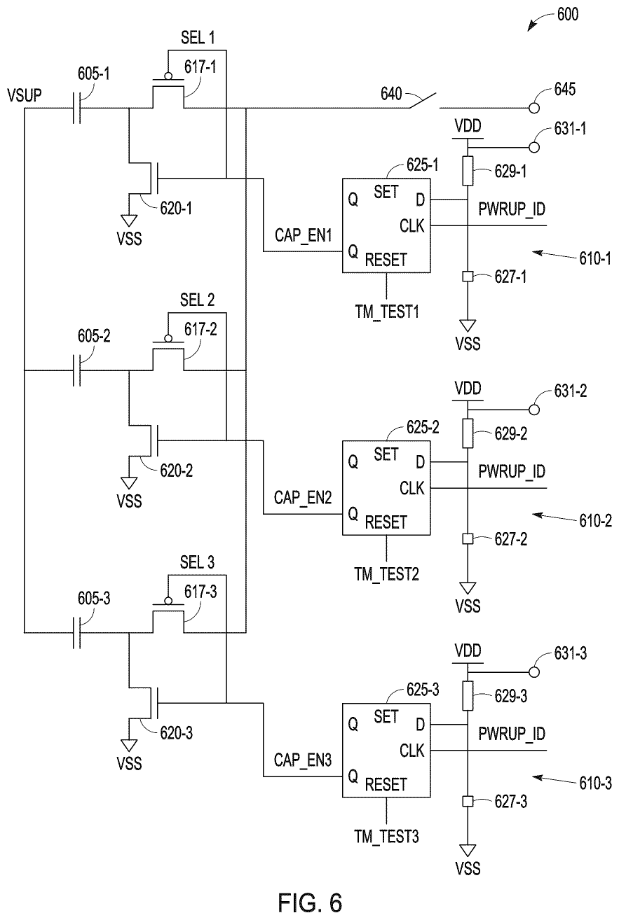

FIG. 6 is a representation of an embodiment of example components of a memory die 600 having a set of detection circuits for a circuit decoupling capacitor to a circuit on the die. The circuit decoupling capacitor can decouple noise from a signal to an input of the circuit (not shown) via a conductive line from a signal source (not shown). The circuit decoupling capacitor can be composed of decoupling capacitors 605-1, 605-2, and 605-3. Decoupling capacitor 605-1 can be coupled to reference voltage VSS by a switch 620-1 that is part of a detection circuit 610-1. Decoupling capacitor 605-2 can be coupled to reference voltage VSS by a switch 620-2 that is part of a detection circuit 610-2. Decoupling capacitor 605-3 can be coupled to reference voltage VSS by a switch 620-3 that is part of a detection circuit 610-3. Each of switches 620-1, 620-2, and 620-3 can be implemented by a NMOS transistor. Decoupling capacitors 605-1, 605-2, and 605-3 can be coupled to a common node providing voltage Vsup, which can be a voltage provided by the source to the circuit that uses the combination of decoupling capacitors 605-1, 605-2, and 605-3. Though three decoupling capacitors and associated detection circuits are shown, memory die 600 can include more or fewer than three decoupling capacitors to form a decoupling capacitor for a circuit and corresponding detection circuits.

Detection circuits 610-1, 610-2, and 610-3 can be arranged to operate in test and retire procedure with respect to an external tester that measures a test current. Detection circuits 610-1, 610-2, and 610-3 can include fuses 627-1, 627-2, and 627-3, respectively. A fuse can be realized by a thin polysilicon line, which by default can be a short having a low resistance, which can approximate zero resistance. A relatively large current can be directed to a fuse to melt and break the fuse, after which the fuse is in an open such that its resistance is permanently high, effectively approximating an infinite resistance. A fuse broken in such a manner is referred to as a blown fuse, which does not conduct current. Using fuses in a capacitor network in a detect and retire mechanism provides a procedure using an external tester that is effectively a one-time procedure in that the testing is performed as part of manufacturing and not an in-line test procedure for a deployed memory device. The testing of a detection architecture using fuses is not provided automatically without use of external testing equipment and is not used for in-the-field retirement operation.

Detection circuit 610-1 includes a select transistor 617-1 that, via a select signal, SEL 1, allows for testing of decoupling capacitor 605-1 to bypass switch 620-1 and for decoupling of the testing of decoupling capacitor 605-1 after testing is complete. Select transistor 617-1 can be coupled to a test pad 645 via a switch 640. A capacitor enable signal, Cap_En1, can be provided to the coupled gates of select transistor 617-1 and switch 620-1, where Cap_EN1 is generated from an output, Q*, of a D flip-flop (DFF) 625-1 that outputs the complement from the signal from output Q of DFF 625-1. DFF 625-1 can be arranged to receive a signal TM_test1 at the RESET of DFF 625-1 and a signal Pwrup_Id at a clock input, CLK, of DFF 625-1. Input D of DFF 625-1 can be coupled to a supply voltage, VDD, through a resistor 629-1, which can be coupled to VDD and to a test pad 631-1. Test pad 631-1 can be coupled to a test controller external to memory die 600. A drive signal can be provided from test pad 631-1 to fuse 627-1 to break fuse 627-1 if external test measurement identifies a current leakage from capacitor 605-1 beyond a threshold leakage current level.

Detection circuit 610-2 includes a select transistor 617-2 that, via a select signal, SEL 2, allows for testing of decoupling capacitor 605-2 to bypass switch 620-2 and for decoupling of the testing of decoupling capacitor 605-2 after testing is complete. Select transistor 617-2 can be coupled to test pad 645 via switch 640. A capacitor enable signal, Cap_En2, can be provided to the coupled gates of select transistor 617-2 and switch 620-2, where Cap_EN2 is generated from an output, Q*, of a DFF 625-2 that outputs the complement from the signal from output Q of DFF 625-2. DFF 625-2 can be arranged to receive signal TM_test2 at the RESET of DFF 625-2 and a signal Pwrup_Id at a clock input, CLK, of DFF 625-2. Input D of DFF 625-2 can be coupled to a supply voltage, VDD, through a resistor 629-1, which can be coupled to VDD and to a test pad 631-2. Test pad 631-2 can be coupled to a test controller external to memory die 600. A drive signal can be provided from test pad 631-2 to fuse 627-2 to break fuse 627-2 if external test measurement identifies a current leakage from capacitor 605-2 beyond a threshold leakage current level.

Detection circuit 610-3 includes a select transistor 617-3 that, via a select signal, SEL 3, allows for testing of decoupling capacitor 605-3 to bypass switch 620-3 and for decoupling of testing of decoupling capacitor 605-3 after testing is complete. Select transistor 617-3 can be coupled to test pad 645 via switch 640. A capacitor enable signal, Cap_En3, can be provided to the coupled gates of select transistor 617-3 and switch 620-3, where Cap_EN1 is generated from an output, Q*, of a DFF 625-3 that outputs the complement from the signal from output Q of DFF 625-3. DFF 625-3 can be arranged to receive signal TM_test3 at the RESET of DFF 625-3 and a signal Pwrup_Id at a clock input, CLK, of DFF 625-3. Input D of DFF 625-3 can be coupled to a supply voltage, VDD, through a resistor 629-3, which is coupled to VDD and to a test pad 631-3. Test pad 631-3 can be coupled to a test controller external to memory die 600. A drive signal can be provided from test pad 631-3 to fuse 627-3 to break fuse 627-3 if external test measurement identifies a current leakage from capacitor 605-3 beyond a threshold leakage current level.

After memory die 600 is provided from fabrication, a time zero power up test, using a pulse for Pwrup_Id, can be generated at which time all fuses 627-1, 627-2, and 627-3 are in a conductive state, which is a state in which the fuses are not blown. At time zero, the DFFs 625-1, 625-2, and 625-3 latch a “0” at their respective Q output, which is a “1” at their Q* output, during power up. Decoupling capacitors 605-1, 605-2, and 605-3 are enabled by default, where enablement means electrically coupling these capacitors to VSS, and SEL 1, SEL 2, and SEL 3 are high decoupling these capacitors from switch 640. Once this state for the capacitors is realized, a detection procedure can be started. Test pad 645, with switch 640 closed, can be forced at 0V and current from test pad 645 can be measured by a controller external to memory die 600. The current from test pad 645 can be continually measured during the detection procedure. A special sequence can be used to toggle signals TM_test1, TM_test2, and TM_test3 one by one to provide decoded test bits. After TM_test1 signal strobe, decoupling capacitor 605-1 is connected to test pad 645 instead of Vss. For measuring decoupling capacitor 605-1 via TM_test1 and SEL 1, a current, Ipad_1, measured through test pad 645, can be logged for analysis. For measuring decoupling capacitor 605-2 via TM_test2 and SEL 2, a current, Ipad_2, measured through test pad 645, can be logged for analysis. For measuring decoupling capacitor 605-3 via TM_test3 and SEL 3, a current, Ipad_3, measured through test pad 645, can be logged for analysis.

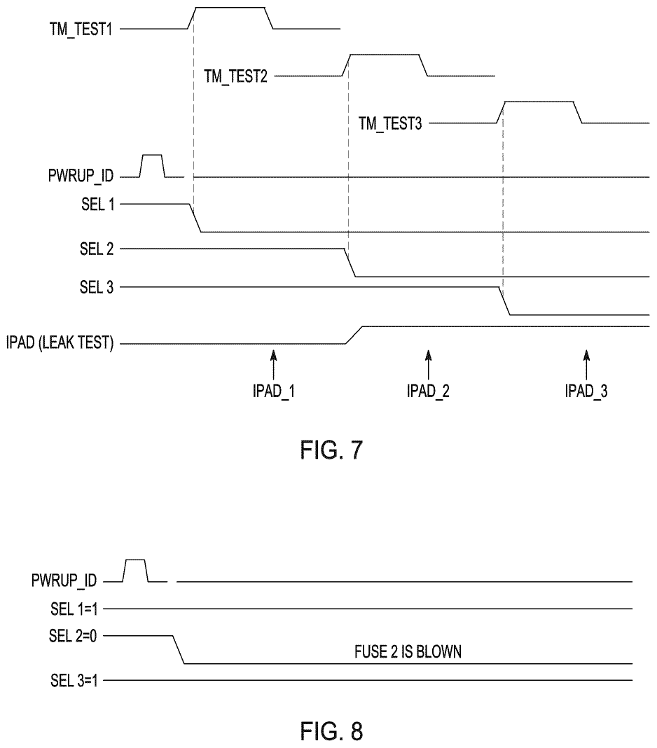

FIG. 7 shows an example of a timing pattern of signals TM_test1, TM_test2, TM_test3, Pwrup_Id, SEL 1, SEL 2, and SEL 3 that provides a current Ipad at test pad 645 for testing in memory die 600 of FIG. 6. If any logged current Ipad_1, Ipad_2, or Ipad_3 is higher than a predefined threshold value, there is a leaking capacitor. The predefined threshold can be, but is not limited to, 0.01 uA. In the example of FIG. 7, after TM_test2 signal strobe, a relatively large current from test pad 645 is observed, which indicates that decoupling capacitor 605-2 is leaking, while decoupling capacitor 605-1 and decoupling capacitor 605-3 are in good condition with respect current leakage. Fuse 629-2 can be blown such that fuse 629-2 approximates an infinite resistance and the signal at the D input of DFF goes high and Cap_En2 goes low turning off switch 620-2 and maintaining switch 620-2 off. The external controller can drive a sufficiently large current to blow fuse 629-2.

FIG. 8 illustrates the status of SEL 1, SEL 2, and SEL 3 of FIG. 7 after fuse 629-2 of FIG. 6 is blown. If a circuit decoupling capacitor, defined by the network of decoupling capacitors 605-1, 605-2, and 605-3, meets specifications for memory die 600 with only one decoupling capacitor leaking, memory die 600 can be deemed functional and placed in service. No further testing is performed and if another decoupling capacitor becomes defective while in service, memory die 600 may become inoperable.

With a circuit decoupling capacitor of an IC, such as a memory die, comprising a capacitor network of N decoupling capacitors having associated detection circuits, where N is significantly larger than three, the detect and retire arrangement of FIG. 6 can be used to maintain operation of the IC and the circuit decoupling capacitor within operational specifications to allow retirement of multiple decoupling capacitors of the network, after fabrication testing, if N is a sufficient number to meet the operational specifications. Depending on the IC, the sufficient number of capacitors can be a number to allow retirement of ten percent of the decoupling capacitors of the decoupling capacitor network, while maintaining operation of the circuit within operational specifications. Depending on the IC, the sufficient number of decoupling capacitors can be a number to allow retirement of one percent of the capacitors of the decoupling capacitor network, while maintaining operation of the circuit within operational specifications. The sufficient number of decoupling capacitors can depend on the design of the IC and the specifications of the application in which the IC is to be placed.

The detect and retire arrangement of FIG. 6, using a network of fuses, can be implemented in an IC, such as a memory die, for testing of failures of the IC corresponding to fabrication defects to be counteracted or for categorizing a tested IC to be deemed failed. The detect and retire arrangement of FIG. 6 can be used in an IC for a decoupling capacitor network to a circuit within the IC that uses a relatively high voltage in the IC, where a defect in decoupling capacitor network is expected to be from processing in fabrication of the IC. In contrast, the detect and retire arrangement of FIG. 2 and the detect and retire arrangement of FIG. 5 can be used in an IC for a decoupling capacitor network to a circuit within the IC that can also use a relatively low voltage in the IC, where a defect can be associated with wear and tear while being operated inline in an apparatus. The detect and retire arrangement of FIG. 6 can also be implemented with the detect and retire arrangement of FIG. 2 or the detect and retire arrangement of FIG. 5 in an IC, such as a memory device, where the detect and retire arrangement of FIG. 6 can be used for a relatively high voltage circuit and the detect and retire arrangement in memory device of FIG. 2 or the detect and retire arrangement of FIG. 5 can be used for a circuit using a lower voltage.

The decoupling capacitor, such as the arrangements of FIGS. 1, 2, 5, 6, or similar architecture, can be realized in a number of different configurations. The decoupling capacitor can be an arrangement of parallel conductive plates, a modification of the capacitive properties of a component device in an IC, a modification of one or more component capacitors of an IC, or other arrangement depending on the architecture of the IC. For example, a decoupling capacitor network of one or more decoupling capacitors can be constructed in a DRAM using component of a memory cell structure of the DRAM. A memory cell structure of the DRAM can include an access transistor coupled to capacitor. With a DRAM fabricated with more memory cell structures than is to be used as addressable memory cells, these excess memory cell structures can be modified to provide the decoupling capacitor and the switch of a detection circuit for the decoupling circuit, as taught herein.

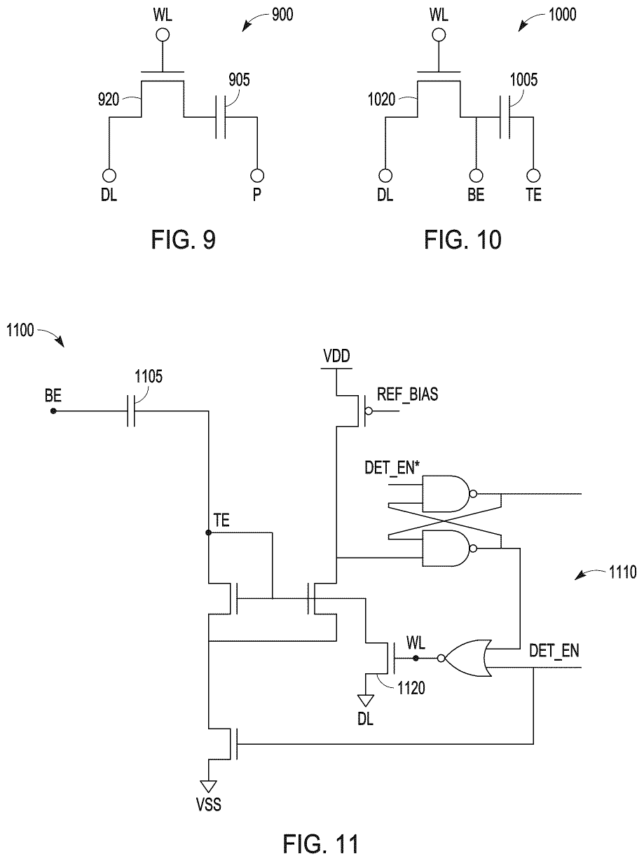

FIG. 9 represents an embodiment of an example memory cell 900 of a DRAM. Memory cell 900 can include an access transistor 920 coupled to a capacitor 905. Access transistor 920 can be a MOS transistor. One electrode of capacitor 905 can be coupled to a plate P, which can provide a common reference voltage such as, but not limited to, VSS or ground. A second electrode of capacitor 905 can be coupled to a source of access transistor 920. The drain of access transistor 920 can be coupled to a digit line, DL, and the gate of access transistor 920 can be coupled to an access line, WL. DL can be a bit line and WL can be a word line. In the memory array of the DRAM, WL can be coupled to multiple access transistors, which are part of a set of memory cells. In the memory array of the DRAM, DL can be coupled to multiple access transistors, which are part of a set of memory cells, with the set of memory cells coupled to DL being different from the set of memory cells coupled to WL, save for one memory cell, which can be memory cell 900.

FIG. 10 represents an embodiment of an example modified memory cell 1000 that can be implemented in a DRAM that includes an array of memory cells 900 of FIG. 9. Modified memory cell 1000 can include an access transistor 1020 coupled to a capacitor 1005. Access transistor 1020 can be a MOS transistor. One electrode of capacitor 1005 can be coupled to a node TE, which in a 3D DRAM can be a top electrode. A second electrode of capacitor can be coupled to a source of access transistor 1020. A node BE can be coupled to a connection of capacitor 1005 with access transistor 1020 that is opposite the connection to node TE, where, in a 3D DRAM, node BE can be a bottom electrode. The drain of access transistor 1020 can be coupled to a digit line, DL, and the gate of access transistor 1020 can be coupled to an access line, WL. Modified memory cell 1000 can be used as a decoupling capacitor and switch in a detection circuit of FIGS. 2, 5, or 6 using nodes DL, BE, and TE coupled to elements of the respective detection circuit constructed in the DRAMs in which the detection circuits are structured. The elements of the detection circuits additional to the modified memory cells, such as memory cell 1000, can use chip space in addition to a conventional chip space used to fabricate the addressable memory cells and circuits to manage and control the functions of the memory cells. The use of such additional chip space can be offset by increased yield in fabrication of such DRAMs that allow detection and retirement of decoupling capacitor of a decoupling capacitor network while maintaining the respective DRAMs suitable for field operation.

FIG. 11 is a representation of an embodiment of example components of a die of a memory device 1100 having a detection circuit 1110 for a decoupling capacitor 1105 using the modified memory cell 1000 of FIG. 10 in the architecture of FIG. 5. Decoupling capacitor 1105 can be implemented using capacitor 1005 of modified memory cell 1000 with BE to couple to the circuit for which decoupling capacitor 1105 is implemented. A switch 1120 can be implemented with access transistor 1020 of modified memory cell 1000 with switch 1120 coupled to DL rather than directly to VSS and with WL of modified memory cell 1000 coupled to the gate of switch 1120 and to a feedback path to switch 1120. Decoupling capacitor 1105 and detection circuit 1110 can be one decoupling capacitor and associated detection circuit of a network of decoupling capacitors.

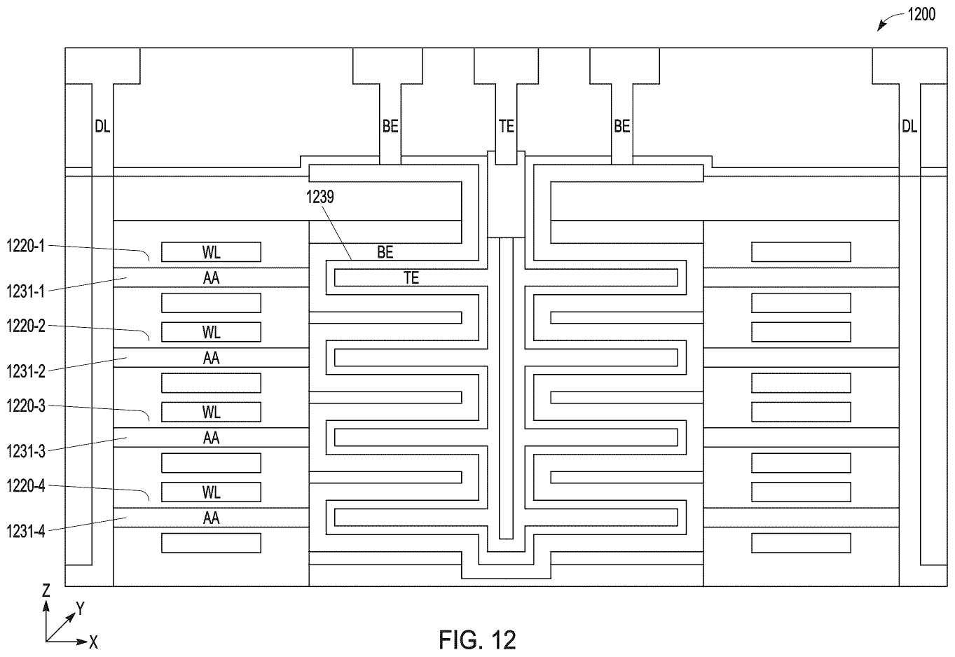

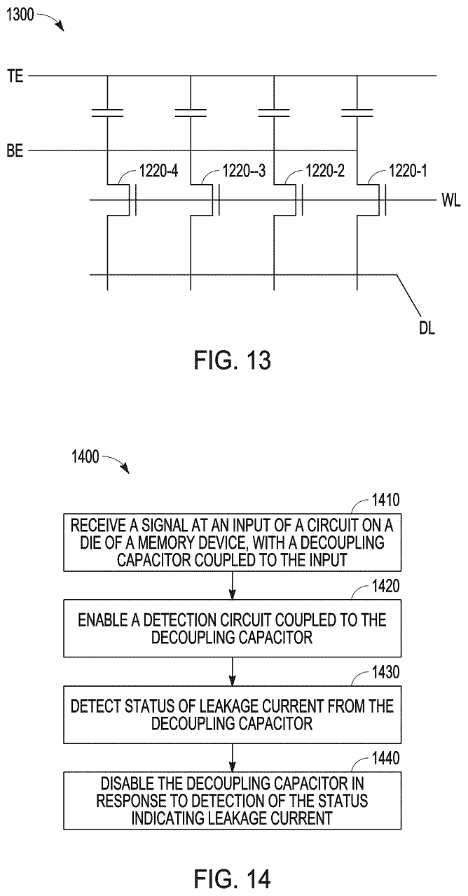

FIG. 12 represents an embodiment of a capacitor applicable as a decoupling capacitor controlled by a switch of a detection circuit in a 3D DRAM 1200. DRAM 1200 can include tiers 1231-1, 1231-2, 1231-3, and 1231-4 of modified memory cells, with the tiers vertically arranged in the z-direction and along the x-direction structured similar to modified memory cell 1000 of FIG. 10. A transistor 1220-1 in tier 1231-1 has a gate separated from an active area, AA, and coupled to a WL. A transistor 1220-2 in tier 1231-2 has a gate separated from an active area, AA, and coupled to a WL. A transistor 1220-3 in tier 1231-3 has a gate separated from an active area, AA, and coupled to a WL. A transistor 1220-4 in tier 1231-4 has a gate separated from an active area, AA, and coupled to a WL. Transistors 1220-1, 1220-2, 1220-3, and 1220-4 can be thin film transistors (TFTs) such as, but not limited to, gate-all-around (GAA) transistors. Though not shown, WL for each of transistors 1220-1, 1220-2, 1220-3, and 1220-4 can be coupled together to form one switch. Each of transistors 1220-1, 1220-2, 1220-3, and 1220-4 can be coupled to a bottom electrode, BE, that is separated from a top electrode, TE, by a dielectric 1239. Each of transistors 1220-1, 1220-2, 1220-3, and 1220-4 can also be coupled to a DL. FIG. 13 is a circuit representation 1300 of transistors 1220-1, 1220-2, 1220-3, and 1220-4 and connections DL, BE, and TE of FIG. 12.

FIG. 14 is a flow diagram of features of an embodiment of an example method 1400 of managing a decoupling capacitor in a die of a memory device. At 1410, a signal is received at an input of a circuit on a die of a memory device, with a decoupling capacitor coupled to the input. The decoupling capacitor is located on the die of the memory device. At 1420, a detection circuit coupled to the decoupling capacitor is enabled, where the detection circuit is located on the die. Operation of the detection circuit can include performing a comparison with a sinking current or a sourcing current.

At 1430, status of leakage current from the decoupling capacitor is detected. The status can be no appreciable leakage, leakage current below a threshold current, leakage current above a threshold current, or leakage. The threshold current can be a reference current generated in the detection circuit. At 1440, the decoupling capacitor is disabled in response to detection of the status indicating leakage current above a threshold current. Procedures of method 1400 can be applied, but is not limited to, architectures discussed herein or similar architectures or approaches to controlling a decoupling capacitor in an integrated circuit.

Variations of method 1400 or methods similar to method 1400 can include a number of different embodiments that may be combined depending on the application of such methods or the architecture or process flow of an IC for which such methods are implemented. Such methods can include disabling the decoupling capacitor by placing a first node of the decoupling capacitor in a floating condition, where the first node is opposite a second node of the decoupling capacitor that is coupled to the input of the circuit.

Variations of method 1400 or methods similar to method 1400 can include disabling the decoupling capacitor that is structured as one decoupling capacitor of a decoupling capacitor network coupled to the input of the circuit, while maintaining other decoupling capacitors of the decoupling capacitor network in operation providing noise decoupling from the signal to the input. The decoupling capacitor network can include a sufficient number of capacitors to maintain operation of the circuit within operational specifications and maintain decoupling for the circuit to allow retirement of multiple decoupling capacitors of the decoupling capacitor network. The sufficient number of capacitors can be ten percent of the capacitors of the decoupling capacitor network. Lower percentages can be used to allow retirement of decoupling capacitors, while maintaining the operation of the die of the memory device. Each decoupling capacitor of the decoupling capacitor network can be coupled to individual detection circuits. Groups of decoupling capacitors of the decoupling capacitor network can be enabled for leakage current detection at the same time. The decoupling capacitors can be monitored for current leakage in groups of one percent of the total number of decoupling capacitors of the decoupling capacitor network coupled to the specific circuit. Larger percentages of the total number of decoupling capacitors of the decoupling capacitor network can be monitored.

Variations of method 1400 or methods similar to method 1400 can include the scheduling of the detection being realized in a number of different manners. The detection can be conducted by continuously monitoring the decoupling capacitor. The detection can be conducted by using a timing circuit of a controller on the die to generate a detection enable signal as an enable pulse. The enable pulse can be generated at start-up of the die of the memory device. The start-up enablement can be conducted in a fabrication phase of the die to address a shorting defect of the decoupling capacitor. Alternatively, the controller on the die can generate an enable pulse at start-up followed by periodic generation of the enable pulse. For example, a first enable pulse of the periodically generated enable pulses can be generated at a time after generating the enable pulse at start-up that is longer than time between the periodically generated enable pulses. Alternatively, the controller on the die can generate an enable pulse at start-up followed by random generation of the enable pulse to perform automatic detection and retirement. The detection and retirement of one or more decoupling capacitors to the input of the circuit can be performed without affecting data storage operation of the die of the memory device.

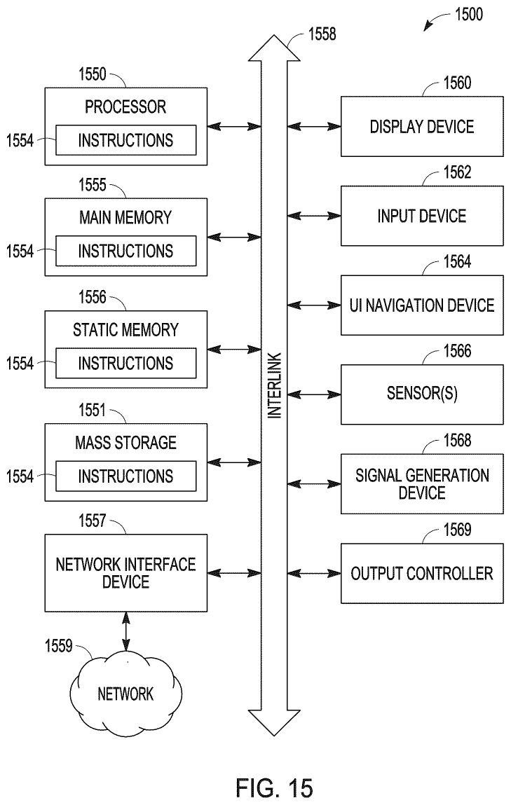

FIG. 15 is a block diagram illustrating an example machine 1500 that can include one or more ICs having capacitor leak detect and retire components, in accordance with discussions herein. The ICs can be, but are not limited to, memory dies. In alternative embodiments, machine 1500 may operate as a standalone device or may be connected (e.g., networked) to other machines. In a networked deployment, machine 1500 may operate in the capacity of a server machine, a client machine, or both in server-client network environments. In an example, machine 1500 may act as a peer machine in peer-to-peer (P2P) (or other distributed) network environment. Machine 1500 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform one or more of methodologies such as, but not limited to, cloud computing, software as a service (SaaS), other computer cluster configuration services, or controlling machine actions using stored instructions or data. Example machine 1500 can include one or more memory devices having a mechanism for detecting and retiring decoupling capacitors in the memory devices. The one or more memory devices can be structured similar to one or more features as discussed with respect to FIGS. 1-14. The one or more memory devices can include one or more 3D memory devices. The 3D memory devices can be 3D DRAMS.

Machine (e.g., computer system) 1500 may include a hardware processor 1550 (e.g., a CPU, a GPU, a hardware processor core, or any combination thereof), a main memory 1555 and a static memory 1556, some or all of which may communicate with each other via an interlink (e.g., bus) 1558. Machine 1500 may further include a display device 1560, an alphanumeric input device 1562 (e.g., a keyboard), and a user interface (UI) navigation device 1564 (e.g., a mouse). In an example, display device 1560, alphanumeric input device 1562, and UI navigation device 1564 may be a touch screen display. Machine 1500 may additionally include a mass storage (e.g., drive unit) 1551, a signal generation device 1568 (e.g., a speaker), a network interface device 1557, and one or more sensors 1566, such as a global positioning system (GPS) sensor, compass, accelerometer, or other sensor. Machine 1500 may include an output controller 1569, such as a serial (e.g., USB, parallel, or other wired or wireless (e.g., infrared (IR), near field communication (NFC), etc.) connection to communicate or control one or more peripheral devices (e.g., a printer, card reader, etc.).

Machine 1500 may include a machine-readable medium on which is stored one or more sets of data structures or instructions 1554 (for example, software or microcode) embodying or utilized by machine 1500. Instructions 1554 may also reside, completely or at least partially, within main memory 1555, within static memory 1556, within mass storage 1551, or within hardware processor 1550 during execution thereof by machine 1500. In an example, one or any combination of hardware processor 1550, main memory 1555, static memory 1556, or mass storage 1551 may constitute machine-readable medium. Machine-readable medium can be a single medium or multiple media (e.g., a centralized or distributed database, or associated caches and servers) configured to store one or more instructions 1554.

The term “machine-readable medium” may include any medium that is capable of storing instructions for execution by machine 1500 and that cause machine 1500 to perform any one or more of the techniques for which machine 1500 is implemented. Non-limiting machine-readable medium examples may include solid-state memories, and optical and magnetic media. Non-volatile machine-readable medium may include semiconductor memory devices such as EPROM, EEPROM, and flash memory devices; magnetic disks, such as internal hard disks and removable disks; magneto-optical disks; and compact disc-ROM (CD-ROM) and digital versatile disc-read only memory (DVD-ROM) disks. Volatile machine-readable medium may include RAM, DRAM, SRAM, or SDRAM.

Instructions 1554 (e.g., software, programs, microcode, an operating system (OS), etc.) or other data stored on mass storage 1551 can be accessed by main memory 1555 for use by processor 1550. Main memory 1555 (e.g., DRAM) is typically fast, but volatile, and thus a different type of storage than mass storage 1551 (e.g., an SSD), which is suitable for long-term storage, including while in an “off” condition. Instructions 1554 or data in use by a user or machine 1500 are typically loaded in main memory 1555 for use by processor 1550. When main memory 1555 is full, virtual space from mass storage 1551 can be allocated to supplement main memory 1555; however, because mass storage 1551 is typically slower than main memory 1555, and write speeds are typically at least twice as slow as read speeds, use of virtual memory can greatly reduce user experience due to storage device latency (in contrast to main memory 1555, e.g., DRAM). Further, use of mass storage 1551 for virtual memory can greatly reduce the usable lifespan of mass storage 1551.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

Instructions 1554 may further be transmitted or received over a network 1559 using a transmission medium via network interface device 1557 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, network interface device 1557 may include one or more physical jacks (e.g., Ethernet, coaxial, or phone jacks) or one or more antennas to connect to network 1559. In an example, network interface device 1557 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of transporting instructions for execution by machine 1500 or data to or from machine 1500. The transportation can include using digital or analog communications signals that can be transmitted over the transmission medium to facilitate communication of such software or data.

The following are example embodiments of devices and methods, in accordance with the teachings herein.

An example memory device 1 can comprise a circuit on a die of the memory device, the circuit having an input to receive a signal, a decoupling capacitor coupled to the input, the decoupling capacitor located on the die, and a detection circuit coupled to the decoupling capacitor, the detection circuit being located on the die. The detection circuit can be structured to detect leakage current from the decoupling capacitor and to disable the decoupling capacitor in response to detection of the leakage current.

An example memory device 2 can include features of example memory device 1 and can include the decoupling capacitor being one decoupling capacitor of a decoupling capacitor network coupled to the input of the circuit.

An example memory device 3 can include features of example memory device 2 and any of the preceding example memory devices and can include the decoupling capacitor network to includes a sufficient number of decoupling capacitors to maintain operation of the circuit within operational specifications and maintain decoupling for the circuit to allow retirement of multiple decoupling capacitors of the decoupling capacitor network.

An example memory device 4 can include features of any of the preceding example memory devices and can include the detection circuit having a comparison circuit arranged to compare current from the decoupling capacitor to a threshold leakage current.

An example memory device 5 can include features of any of the preceding example memory devices and can include the detection circuit including a comparison circuit with a sinking current.

An example memory device 6 can include features of any of the preceding example memory devices and can include the detection circuit including a comparison circuit with a sourcing current.

An example memory device 7 can include features of any of the preceding example memory devices and can include the detection circuit including a switch to enable decoupling operation of the decoupling capacitor by operatively coupling the decoupling capacitor to a reference voltage.

An example memory device 8 can include features of example memory device 7 and any of the preceding example memory devices and can include the switch being a metal-oxide-semiconductor field effect transistor.

An example memory device 9 can include features of any of the preceding example memory devices and can include the circuit being a sense amplifier circuit.

An example memory device 10 can include features of any of the preceding example memory devices and can include the die being a dynamic random-access memory die and the decoupling capacitor being structured from coupling a group of formed memory cell structures, the memory cell structures modified not to store data.

In an example memory device 11, any of the memory devices of example memory devices 1 to 10 may be incorporated into an electronic apparatus further comprising a host processor or memory controller and a communication bus extending between the host processor/memory controller and the memory device.

In an example memory device 12, any of the memory devices of example memory devices 1 to 11 may be modified to include any structure presented in another of example memory device 1 to 11.

In an example memory device 13, any apparatus associated with the memory devices of example memory devices 1 to 12 may further include a machine-readable storage device configured to store instructions as a physical state, wherein the instructions may be used to perform one or more operations of the apparatus.

In an example memory device 14, any of the memory devices of example memory devices 1 to 13 may be formed or operated in accordance with any of the below example methods 1 to 7.

An example memory device 15 can comprise a signal source and a circuit on a die of the memory device, where the circuit has an input coupled to receive a signal from the signal source. Example memory device 15 can include a decoupling capacitor coupled to the input, where the decoupling capacitor is located on the die, a detection circuit coupled to the decoupling capacitor, where the detection circuit is located on the die, and a controller, on the die, coupled to the detection circuit to control a detection enable signal to the detection circuit. The detection circuit can be structured to detect leakage current from the decoupling capacitor and to disable the decoupling capacitor in response to detection of the leakage current.

An example memory device 16 can include features of example memory device 15 and can include the controller including a timing circuit to generate the detection enable signal as an enable pulse.

An example memory device 17 can include features of example memory device 15 and example memory device 16 and can include the enable pulse being generated at start-up and subsequently periodically.

An example memory device 18 can include features of example memory device 17 and any of the preceding example memory devices 15 or 16 and can include a first enable pulse of the periodically generated enable pulses is generated at a time after generating the enable pulse at start-up that is longer than time between the periodically generated enable pulses.

An example memory device 19 can include features of any of the preceding example memory devices 15 to 18 and can include the controller being structured to control the detection circuit without affecting data storage operation of the die of the memory device.

An example memory device 20 can include features of any of the preceding example memory devices 15 to 19 and can include the detection circuit including: a switch transistor coupled to a reference voltage node and coupled to the decoupling capacitor at a first node of the decoupling capacitor opposite a second node of the decoupling capacitor, the second node coupled to the input of the circuit; a current mirror coupled to the first node by an detection enabling transistor; and a feedback circuit coupling the current mirror to the switch transistor.

An example memory device 21 can include features of any of the preceding example memory devices 15 to 20 and can include the detection circuit including: a current mirror coupled to the decoupling capacitor at a first node of the decoupling capacitor opposite a second node of the decoupling capacitor, the second node coupled to the input of the circuit; a switch transistor coupled to a reference voltage node and to transistor gates of the current mirror; and a feedback circuit coupling the current mirror to the switch transistor.

In an example memory device 22, any of the memory devices of example memory devices 15 to 21 may be incorporated into an electronic apparatus further comprising a host processor or memory controller and a communication bus extending between the host processor/memory controller and the memory device.

In an example memory device 23, any of the memory devices of example memory devices 15 to 22 may be modified to include any structure presented in another of example memory device 15 to 22.

In an example memory device 24, any apparatus associated with the memory devices of example memory devices 15 to 23 may further include a machine-readable storage device configured to store instructions as a physical state, wherein the instructions may be used to perform one or more operations of the apparatus.

In an example memory device 25, any of the memory devices of example memory devices 15 to 24 may be formed or operated in accordance with any of the below example methods 1 to 7.

An example method 1 can comprise receiving a signal at an input of a circuit on a die of a memory device, with a decoupling capacitor coupled to the input, the decoupling capacitor located on the die; enabling a detection circuit coupled to the decoupling capacitor, the detection circuit being located on the die; detecting status of leakage current from the decoupling capacitor; and disabling the decoupling capacitor in response to detection of the status indicating leakage current above a threshold current.

An example method 2 can include features of example method 1 and can include disabling the decoupling capacitor to include placing a first node of the decoupling capacitor in a floating condition, the first node being opposite a second node of the decoupling capacitor, the second node coupled to the input of the circuit.

An example method 3 can include features of any of the preceding example methods and can include disabling the decoupling capacitor to include disabling the decoupling capacitor structured as one decoupling capacitor of a decoupling capacitor network coupled to the input of the circuit, while maintaining other decoupling capacitors of the decoupling capacitor network in operation providing noise decoupling from the signal to the input.

In an example method 4, any of the example methods 1 to 3 may be performed in operating a memory device further comprising a host processor and a communication bus extending between the host processor and a memory device.

In an example method 5, any of the example methods 1 to 4 may be modified to include operations set forth in any other of example methods 1 to 4.

In an example method 6, any of the example methods 1 to 5 may be implemented at least in part through use of instructions stored as a physical state in one or more machine-readable storage devices.

An example method 7 can include features of any of the preceding example methods 1 to 6 and can include performing functions associated with any features of example memory devices 1 to 25.

An example machine-readable storage device storing instructions, that when executed by one or more processors, cause a machine to perform operations, can comprise instructions to perform functions associated with any features of example memory devices 1 to 25 or perform methods associated with any features of example methods 1 to 7.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
a circuit on a die of the memory device, the circuit having an input to receive a signal;
a decoupling capacitor coupled to the input, the decoupling capacitor located on the die; and
a detection circuit coupled to the decoupling capacitor, the detection circuit being located on the die and structured to detect leakage current from the decoupling capacitor and to disable the decoupling capacitor in response to detection of the leakage current.

2. The memory device of claim 1, wherein the decoupling capacitor is one decoupling capacitor of a decoupling capacitor network coupled to the input of the circuit.

3. The memory device of claim 2, wherein the decoupling capacitor network includes a sufficient number of decoupling capacitors to maintain operation of the circuit within operational specifications and maintain decoupling for the circuit to allow retirement of multiple decoupling capacitors of the decoupling capacitor network.

4. The memory device of claim 1, wherein the detection circuit includes a comparison circuit arranged to compare current from the decoupling capacitor to a threshold leakage current.

5. The memory device of claim 1, wherein the detection circuit includes a comparison circuit with a sinking current.

6. The memory device of claim 1, wherein the detection circuit includes a comparison circuit with a sourcing current.

7. The memory device of claim 1, wherein the detection circuit includes a switch to enable decoupling operation of the decoupling capacitor by operatively coupling the decoupling capacitor to a reference voltage.

8. The memory device of claim 7, wherein the switch is a metal-oxide-semiconductor field effect transistor.

9. The memory device of claim 1, wherein the circuit is a sense amplifier circuit.

10. The memory device of claim 1, wherein the die is a dynamic random-access memory die and the decoupling capacitor is structured from coupling a group of formed memory cell structures, the memory cell structures modified not to store data.

11. A memory device comprising:
a signal source;
a circuit on a die of the memory device, the circuit having an input coupled to receive a signal from the signal source;
a decoupling capacitor coupled to the input, the decoupling capacitor located on the die;
a detection circuit coupled to the decoupling capacitor, the detection circuit being located on the die and structured to detect leakage current from the decoupling capacitor and to disable the decoupling capacitor in response to detection of the leakage current; and
a controller, on the die, coupled to the detection circuit to control a detection enable signal to the detection circuit.

12. The memory device of claim 11, wherein the controller includes a timing circuit to generate the detection enable signal as an enable pulse.

13. The memory device of claim 12, wherein the enable pulse is generated at start-up and subsequently periodically.

14. The memory device of claim 13, wherein a first enable pulse of the periodically generated enable pulses is generated at a time after generating the enable pulse at start-up that is longer than time between the periodically generated enable pulses.

15. The memory device of claim 11, wherein the controller is structured to control the detection circuit without affecting data storage operation of the die of the memory device.

16. The memory device of claim 11, wherein the detection circuit includes:
a switch transistor coupled to a reference voltage node and coupled to the decoupling capacitor at a first node of the decoupling capacitor opposite a second node of the decoupling capacitor, the second node coupled to the input of the circuit;
a current mirror coupled to the first node by an detection enabling transistor; and
a feedback circuit coupling the current mirror to the switch transistor.

17. The memory device of claim 11, wherein the detection circuit includes:
a current mirror coupled to the decoupling capacitor at a first node of the decoupling capacitor opposite a second node of the decoupling capacitor, the second node coupled to the input of the circuit;
a switch transistor coupled to a reference voltage node and to transistor gates of the current mirror; and
a feedback circuit coupling the current mirror to the switch transistor.

18. A method comprising:
receiving a signal at an input of a circuit on a die of a memory device, with a decoupling capacitor coupled to the input, the decoupling capacitor located on the die;
enabling a detection circuit coupled to the decoupling capacitor, the detection circuit being located on the die;
detecting status of leakage current from the decoupling capacitor; and
disabling the decoupling capacitor in response to detection of the status indicating leakage current above a threshold current.

19. The method of claim 18, wherein disabling the decoupling capacitor includes placing a first node of the decoupling capacitor in a floating condition, the first node being opposite a second node of the decoupling capacitor, the second node coupled to the input of the circuit.

20. The method of claim 18, wherein disabling the decoupling capacitor includes disabling the decoupling capacitor structured as one decoupling capacitor of a decoupling capacitor network coupled to the input of the circuit, while maintaining other decoupling capacitors of the decoupling capacitor network in operation providing noise decoupling from the signal to the input.
